(19) United States
(12) Patent Application Publication
(10) Pub. No.: US 2003/0087043 A1
(43) Pub. Date: May 8, 2003

(54) Low k dielectric film deposition process

(75) Inventors: Daniel C. Edelstein, White Plains, NY (US); William J. Cote, Poughkeepsie, NY (US); Timothy J. Dalton, Ridgefield, CT (US); Christopher V. Jahnes, Upper Saddle River, NJ (US); Gill Young Lee, Wappingers Falls, NY (US)

Correspondence Address: Philmore H. Colburn II, Cantor Colburn LLP, 55 Griffin Road South, Bloomfield, CT, 06002, US

(73) Assignee: INTERNATIONAL BUSINESS MACHINES CORPORATION, ARMONK, NY (US)

(21) Appl. No.: 10/005,861

(22) Filed: Nov. 8, 2001

(51) Int. Cl. C23C 16/00

(52) U.S. Cl. 427/569; 427/255.28; 427/249.15

(57) ABSTRACT

A process of depositing a low k dielectric film on a substrate includes using plasma enhance chemical vapor deposition to deposit a hydrogenated oxidized silicon carbon film. The process includes flowing a precursor gas containing Si, C, H and an oxygen-providing gas into the PECVD chamber. The precursor gas and the oxygen-providing gas are substantially free from nitrogen. The oxygen-providing gas is selected from the group consisting of oxygen, carbon monoxide, carbon dioxide, ozone, water vapor and a combination of at least one of the foregoing.

### BACKGROUND OF THE INVENTION

The present disclosure relates to low k dielectric materials and in particular, to a process for depositing a low k dielectric film (a film having low capacitance) onto a substrate for use in integrated circuit manufacture.

New insulating materials for advanced interconnects such as low k dielectric films have been proposed, which when used in the integrated circuit structure lowers interconnect capacitance and crosstalk noise to enhance circuitry performance. The low k dielectric films are generally materials containing Si, C, O and H and have dielectric constants less than about 4.0. The materials may be polymeric or non-polymeric. Some examples of commercially available low k dielectric materials include organosilicate glasses, methylsiloxane, methylsesquioxanes, hydrogen silsesquioxanes, polyimides, parylenes, fluorocarbons, benzocyclobutenes and other organic and inorganic materials.

The use of plasma enhanced chemical vapor deposition (PECVD) processes to produce traditional dielectric films such as SiO₂ or SiN on semiconductor devices is well known in the art. PECVD processes typically include introducing a gaseous silicon-containing material and a reactive gas into a reaction chamber containing a semiconductor substrate. An energy source, such as thermal energy or plasma energy, induces a reaction between the silicon-containing material and reactive gas resulting in the deposition of a thin dielectric film on the semiconductor device.

PECVD processes are also commonly used for depositing low k dielectric films onto a substrate. The PECVD process typically includes exposing a silicon-containing gas precursor, such as methylsilane or trimethylsilane, and a nitrogen containing oxidizing gas, such as nitrous oxide, to a plasma at temperatures less than 500° C. The low k dielectric films formed from these components have been found to contain a small amount of byproduct amine within the dielectric structure that causes problems during photolithography.

Photolithography includes the use of photoresists to define the circuitry patterned into the integrated circuit. The photoresists used with the low k films are generally based on a chemical amplification mechanism. It has been found that patterning chemically amplified photoresists onto low k dielectric films that contain a small amount of byproduct amine within the dielectric structure results in footing. Footing can be attributed to neutralization or poisoning of the catalytic amount of acid generated during exposure of the chemically amplified photoresist. Normally, upon exposure to light, a photoacid generator component in the chemically amplified photoresist formulation generates a catalytic amount of acid within the exposed regions. The catalytic amount of acid then reacts with the polymer component of the photoresist formulation causing a dissolution differential between the exposed and unexposed regions. Subsequent development results in a relief image formed in the photoresist layer. However, if the underlying low k dielectric film has residual amine functionalities present within its structure, the presence of these amines neutralize or poison the catalytic amount of acid generated in the exposed regions, thereby changing the dissolution behavior within the exposed regions. Since the amine functionality is present on the surface of the low k dielectric structure, neutralization of the acid is most easily observed as footing at an interface between the dielectric and photoresist.

### SUMMARY OF THE INVENTION

A method of depositing a low k dielectric film on a substrate employing plasma enhanced chemical vapor deposition is disclosed. The process includes providing a substrate in a PECVD chamber; flowing a precursor gas containing Si, C, H and an oxygen-providing gas into the PECVD chamber; and depositing a hydrogenated oxidized silicon carbon film on the substrate. The precursor gas and the oxygen-providing gas are substantially free of nitrogen.

In one embodiment, the oxygen-providing gas is selected from the group consisting of oxygen, carbon monoxide, carbon dioxide, ozone, water or a combination comprising at least one of the foregoing. The precursor gas is selected from the group consisting of methylsilane, dimethylsilane, trimethylsilane, tetramethylsilane, 1,3,5,7tetra-methyl-cyclo-tetra-siloxane, tetraethylcyclotetrasiloxane, and decamethylcyclopentasiloxane silanes or combinations comprising at least one of the foregoing.

In another embodiment, the precursor gas is selected from the group consisting of methylsilane, dimethylsilane, trimethylsilane and tetramethaylsilane. The oxygen-providing gas is selected from the group consisting of oxygen, carbon monoxide, water vapor, carbon dioxide or a combination comprising at least one of the foregoing.

Other embodiments are contemplated to provide particular features and structural variants of the basic elements. The specific embodiments referred to as well as possible variations and the various features and advantages of the invention will become better understood when considered in connection with the detailed description and drawings that follow.

### BRIEF DESCRIPTION OF THE DRAWINGS

FIG. 1 is a cross sectional view showing a parallel plate chemical vapor deposition chamber.

FIG. 2 are scanning electron microscopy micrographs of nested features patterned on a low k dielectric film.

FIG. 3 illustrate FTIR spectra for SiCOH low k dielectric films produced using various Si, C and H precursors and N₂O as the oxygen providing gas.

FIG. 4 illustrate FTIR spectra for SiCOH low k dielectric films produced using various Si, C and H precursors and CO₂ as the oxygen providing gas.

### DETAILED DESCRIPTION OF PREFERRED EMBODIMENTS

A process for forming on a substrate a low k dielectric film suitable for lithographically patterning photoresists thereon is described. The low k dielectric films formed preferably have a dielectric constant less than about 4.0. Generally, the process includes providing a substrate in a PECVD chamber and flowing into the chamber a precursor gas containing Si, C and H with an oxygen-providing gas, which gases are substantially free from nitrogen. An energy source, such as thermal energy and/or plasma energy, within the PECVD induces a reaction between the precursor gas and the oxygen-providing gas to deposit onto the substrate a hydrogenated oxidized silicon carbon film (SiCOH), which is substantially free of nitrogen. Advantageously, the SiCOH low k dielectric films do not contain byproduct amines within its structure. Photoresists processed on the SiCOH low k dielectric film, including those photoresists having chemically amplified mechanisms, advantageously do not exhibit footing.

The substrate may be a semiconductor wafer or chip which is composed of any Si-containing semiconductor material such as, but not limited to Si, SiGe, SiO₂, GaAs, Si/SiGe, Si/SiO₂/Si and other like Si containing semiconductor materials. The substrate may be of the n- or p-type depending on the desired device to be fabricated. Moreover, the substrate may contain various isolation and/or device regions formed in the substrate or on a surface thereof. The substrate may also contain metallic pads on the surface thereof. For clarity, the above mentioned regions and metallic pads are not shown in the drawings, but are nevertheless meant to be included with the substrate. In addition to Si-containing semiconductor materials, the substrate may also be a circuit that includes CMOS devices therein, or alternatively, substrate may be one of the interconnect levels of the interconnect structure.

The process for depositing the low k dielectric material onto the substrate includes providing a precursor gas containing Si, C, H with an oxygen-providing gas, which are substantially free from nitrogen, and exposing the gas mixture to an energy source. Preferably, the Si-containing precursor gas is selected from molecules such as methyl silane (1MS), tri-methyl silane (3MS) or tetra-methyl silane (4MS). However, other precursors comprising Si, C, H, and O, such as 1,3,5,7-tetramethylcyclotetrasiloxane (TMCTS, or C₄H₁₆O₄Si₄), tetraethylcyclotetrasiloxane (C₈H₂₄O₄Si₄), or decamethylcyclopentasiloxane (C₁₀H₃₀O₅Si₅) containing gases may also be used.

The precursor gases can be delivered directly as a gas to the chamber, delivered as a liquid vaporized directly within the chamber, or transported by an inert carrier gas such as helium or argon. If the precursor gas has sufficient vapor pressure, no carrier gas may be needed. Optionally, hydrogen, germanium or fluorine containing gases can be added to the gas mixture in the reactor if need to modify the low-k film properties. The SiCOH films may thus contain atoms of Ge and F.

The oxygen-providing gas includes those compounds that contain oxygen that are substantially free from nitrogen. Suitable oxygen-providing gases include carbon monoxide, carbon dioxide, oxygen, o-zone, water vapor and the like. Preferably, the oxygen-providing gas is oxygen, carbon monoxide or carbon dioxide or mixtures thereof. Similar to the precursor, the oxygen-providing gas can be delivered directly as a gas to the chamber or transported with an inert carrier or diluent gas such as helium, argon., xenon, krypton, or the like.

The SiCOH low k dielectric films formed by PECVD preferably have dielectric constants less than about 4.0, with less than about 3.5 more preferred and with less than 3.0 most preferred. If required, the deposited SiCOH films may be further stabilized before undergoing further integration processing to either evaporate residual contents in the deposited films and to dimensionally stabilize the films or just dimensionally stabilize the films. The stabilization process can be carried out in a furnace at between about 300° C. and about 500° C. for a time period between about 0.5 and about 4 hours. Alternatively, the stabilization can be performed by a rapid thermal annealing process at temperatures greater than about 300° C.

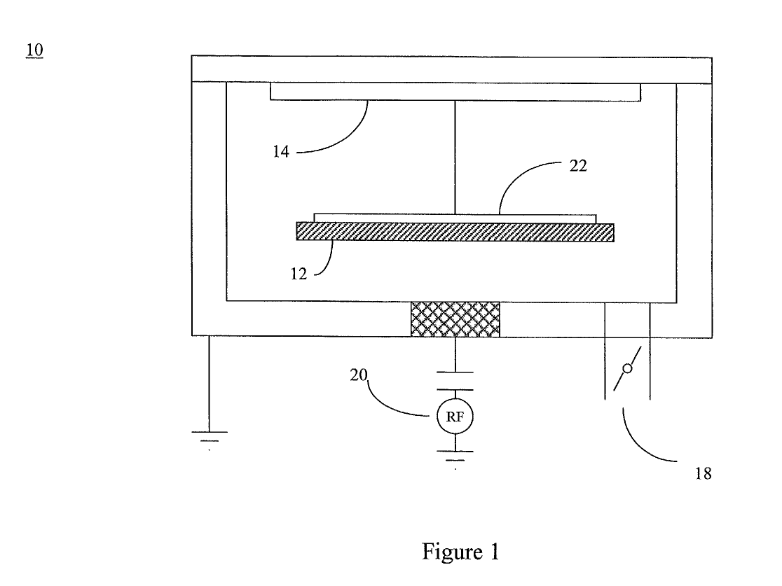

Referring now to FIG. 1 wherein a simplified view of a PECVD reactor 10 for processing 200 mm wafers is shown. The precursor gases are introduced into the reactor 10 through a gas distribution plate (GDP) 14 and are pumped out through a pumping port 18. The GDP is separated from a grounded substrate chuck 12 by a gap, An RF power source 20 is connected to GDP 14 for establishing a plasma between GDP 14 and grounded substrate chuck 12. For practical purposes, all other parts of the reactor are grounded through a protective insulative coating or cover (not shown). Substrate 22 thus acquires a negative bias, whose value depends on the reactor geometry and plasma parameters. In a different embodiment, the RF power 20 can be connected to the substrate chuck 12 and the GDP 14 is grounded. Alternatively, more than one electrical power supply can be used. For instance, two power supplies can operate at the same RF frequency, or one may operate at a low frequency and one at a high. frequency. The two power supplies may be connected both to same electrode or to separate electrodes. Optionally, the RF power supply is pulsed on and off during film deposition.

Process variables controlled during deposition of low-k films are RF power, precursor gas and oxygen-providing gas mixture and flow rates, pressure in reactor, and substrate temperature. Optimization of these variables is well within the skill of those in the art. The factors of most importance are the wafer temperature during film growth, power density and pressure of the system, the gas flow rates, and the oxygen-providing gas to precursor gas flow rate ratio. The exact process conditions will vary depending on the type and design of the reactor used. Preferably, the temperature of the wafer or substrate during growth is from about 25° C. to about 500° C. The power density and pressure are preferably from about 0.02 W/cm² to about 4 W/cm² and about 5 mTorr to about 10 Torr, respectively. The gas flow rates will vary depending on the molecules used. Preferably, the individual gas flow rates are from about 5 sccm to about 600 sccm.

In an exemplary embodiment, the plasma chamber includes a plasma source with a configuration such that the substrate electrode is grounded, and the excitation is at a power density in the range of about 0.1 W/cm² to about 2.4 W/cm². If the plasma source includes a configuration with the substrate electrode connected to the RF then this power would be much lower, preferably in the range of about 0.01 w/cm² to about 1.0 w/cm². The process conditions are strongly a function of the precursor gas employed and the design of the reactor. For example, in the case of a plasma system, low excitation power generally produces lower density films and higher powers produce more dense films. If the excitation power is too high, the film becomes SiO₂-like and the dielectric constant becomes too high. If the excitation power is too low then the structural integrity of the films will be undesirably poor. Further, when the power is too low, or the plasma chemistry has not been properly determined, it is possible under some circumstances to create undesirable groups in the films. Under such conditions, peaks associated with Si—OH have been observed in the FTIR spectra and the dielectric constant is higher than desired.

The amount of oxygen-providing gas will vary depending on the silicon containing precursor, the molecule used for the oxygen source, reactor design and process conditions used. For example, the percent concentration of oxygen gas used with tri-methylsilane is a function of the process conditions, such as wafer temperature, the RF power, pressure, and the total gas flow rates. Too much oxygen-providing gas will result in a film that is a SiO₂-like material. Too little oxygen generally results in a film with less oxygen incorporation and a resulting dielectric constant greater than 3.5.

A preferred gas mixture includes trimethylsilane, an oxygen-providing gas and helium as a diluent using a common commercial PECVD reactor configured with the RF power applied to the GDP. Example optimal conditions used include trimethylsilane at a flow rate of about 300 sccm, oxygen-providing gas at a flow rate of about 100 sccm, and a helium flow rate at about 1900 sccm at a pressure of 4 torr, a wafer temperature of 350° C., and an RF power of 600 watts. Under these conditions, the deposited film has a dielectric constant of 2.7, a hardness value of 1.4 GPa and no detectable N—H groups within its structure by FTIR analysis.

Although one type of reactor has been described, it will be understood to those skilled in the art that different types of reactors may be employed to deposit the film. For example, thermal CVD reactors may be used that operate at either atmospheric pressure, sub-atmospheric pressure or at low pressure conditions. In a thermal CVD system, the organosilicon is degraded thermally in the presence of an oxidizing agent. Control of the chamber temperature, the nature of the oxidizing agent (such as ozone, hydrogen peroxide, and/or oxygen), and the concentration of the oxidizing agent is fundamental for producing low k dielectric films.

The following examples fall within the scope of, and serve to exemplify, the more generally described methods set forth above. The examples are presented for illustrative purposes only, and are not intended to limit the scope of the invention.

### EXAMPLES

### Example 1

In this example, SiCOH low k dielectric films were deposited under similar conditions using PECVD. A trimethylsilane precursor gas containing Si, C, H and an oxygen-providing gas were exposed to an energy source within the PECVD chamber. The oxygen-providing gas used to form the dielectric film was either nitrous oxide or oxygen. A chemically amplified DUV photoresist (Shipley UV82) was then deposited under identical conditions onto the dielectric film and subsequently patterned.

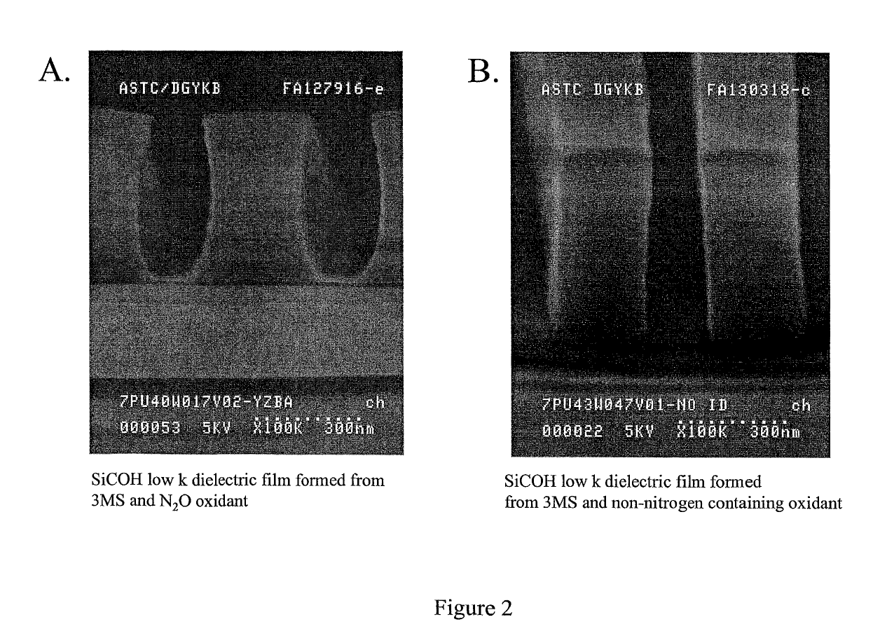

FIG. 2 pictorially shows scanning electron micrographs of cross sections of the substrate including the patterned photoresist and low k dielectric film. Clearly evident is a significant amount of footing for the photoresist patterned on the SiCOH low k dielectric film formed using nitrous oxide as shown in FIG. 2A. In contrast, patterning the photoresist on the SiCOH low k dielectric film formed from oxygen gas exhibited no footing as shown in FIG. 2B. The footing is believed to be caused by an interaction between the amine groups in the low k dielectric film and the acid generated in the photoresist during patterning. Since only catalytic amounts of acid are generated, neutralization of only a small amount of acid produces undesirable results.

### Example 2

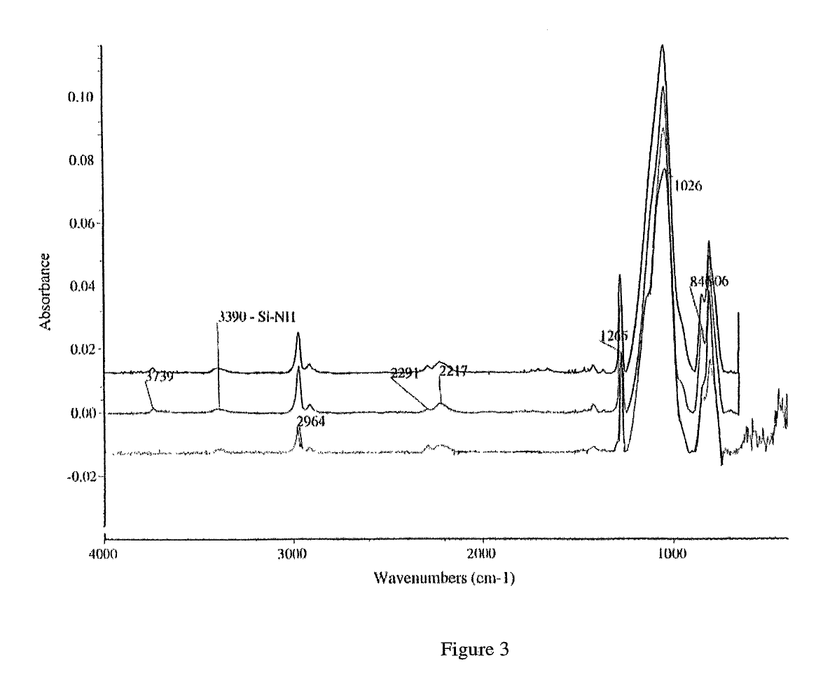

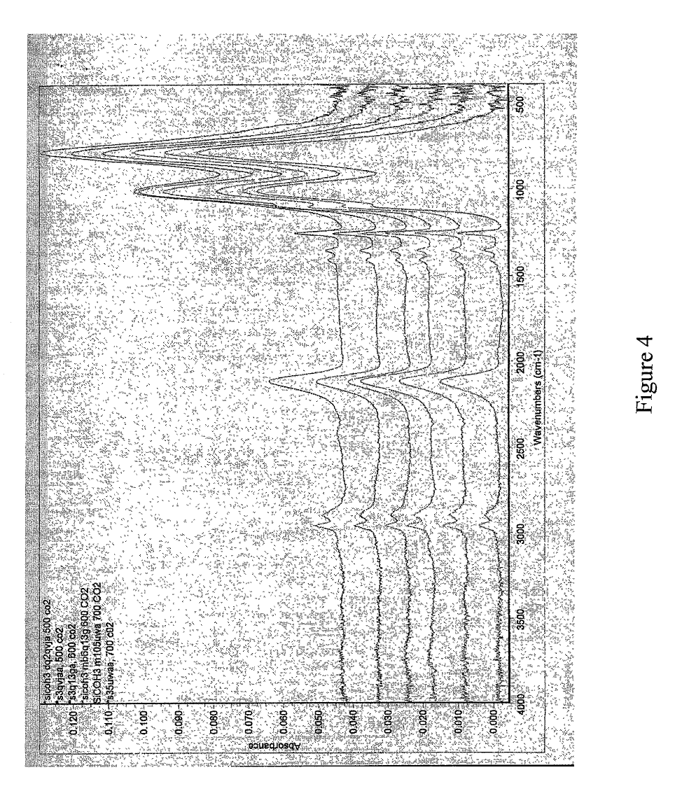

In this example, SiCOH low k dielectric films were deposited under similar conditions using PECVD and analyzed by FTIR. The first film employed a nitrous oxide oxidizing agent whereas the second film employed carbon dioxide oxygen gas as the oxidizing agent. The precursor gas was trimethylsilane. As shown in FIG. 3, the use of nitric oxide as the oxidant resulted in the formation of amine groups as evidenced by a small peak at about 3390 cm⁻¹. In contrast, as shown in FIG. 4, SiCOH low k dielectric films formed using carbon dioxide as the oxidant exhibited no evidence for the formation of amine functionalities. Moreover, the use of these films did not result in photoresist footing during subsequent photolithography.

While preferred embodiments have been shown and described, various modifications and substitutions may be made thereto without departing from the spirit and scope of the invention. Accordingly, it is understood that the present invention has been described by way of illustrations and not limitation.

We claim:

1. A method of depositing a low k dielectric film on a substrate, the method comprising
flowing a precursor gas containing Si, C, H and an oxygen-providing gas into a PECVD chamber containing a substrate, wherein the precursor gas and the oxygen-providing gas are substantially free of nitrogen, and wherein the oxygen-providing gas is selected from the group consisting of oxygen, carbon monoxide, carbon dioxide, ozone, water vapor and a combination comprising at least one of the foregoing; and
depositing a hydrogenated oxidized silicon carbon film on the substrate.

2. The method according to claim 1, wherein the precursor gas is selected from the group consisting of methylsilane, dimethylsilane, trimethylsilane, tetramethylsilane, 1,3,5,7-tetra-methyl-cyclo-tetra-siloxane, tetraethylcyclotetrasiloxane, and decamethylcyclopentasiloxane silanes and combinations comprising at least one of the foregoing.

3. The method according to claim 1, wherein the precursor gas is selected from the group consisting of methylsilane, dimethylsilane, trimethylsilane, tetramethylsilane, and combinations comprising at least one of the foregoing.

4. The method according to claim 1, further comprising heating the PECVD chamber to a temperature ranging from 25° C. to 500° C.

5. The method according to claim 1, wherein the oxygen-providing gas is selected from the group consisting of oxygen, carbon monoxide, water vapor, carbon dioxide and a combination comprising at least one of the foregoing.

6. The method according to claim 1 wherein the precursor gas comprises an organosilicon compound having a ring structure selected from the group consisting of 1,3,5,7-tetramethylcyclotetrasiloxane, tetraethylcyclotetrasiloxane, and decamethylcyclopentasiloxane.

7. The method according to claim 1, wherein the hydrogenated oxidized silicon carbon film has a dielectric constant less than 3.5.

8. The method according to claim 1, wherein the hydrogenated oxidized silicon carbon film has a dielectric constant less than 3.0.

9. The method according to claim 1, wherein the hydrogenated oxidized silicon carbon film has a dielectric constant of about 2.7.

10. The method according to claim 1, wherein the hydrogenated oxidized silicon carbon film is free from amine functionalities.

11. The method according to claim 1, further comprising annealing the hydrogenated oxidized silicon carbon film at a temperature greater than 300° C.

12. The method according to claim 1, wherein the plasma enhanced chemical vapor deposition chamber is a parallel plate plasma reactor.

13. The method according to claim 1, further comprising flowing a diluent gas.

14. The method according to claim 13, wherein the diluent gas is selected from the group consisting of helium, argon, xenon, and krypton.

15. The method according to claim 1, wherein a flow rate ratio of the precursor gas to the oxygen providing gas is from about 10:1 to about 1:5.

16. The method according to claim 1, wherein the hydrogenated oxidized silicon carbon film is non-polymeric.

17. A method of depositing a low k dielectric film on a substrate, the method comprising
providing a substrate in a PECVD chamber;
flowing a precursor gas containing Si, C, H, an oxygen-providing gas, and a carrier gas into the PECVD chamber, the precursor gas and the oxygen-providing gas being substantially free of nitrogen and, wherein the oxygen-providing gas is selected from the group consisting essentially of oxygen, carbon monoxide, carbon dioxide, water and combinations of at least one of the foregoing; and
depositing a nitrogen-free SiCOH dielectric film onto the substrate, wherein the SiCOH dielectric film includes a dielectric constant less than 3.5.

18. The method according to claim 17, wherein the precursor gas is selected from the group consisting of methylsilane, dimethylsilane, trimethylsilane, tetramethylsilane, and combinations of at least one of the foregoing.

19. The method according to claim 17, wherein the nitrogen-free SiCOH dielectric film comprises a hydrogenated oxidized silicon carbon film.
